(19) United States
(12) Patent Application Publication
(10) Pub. No.: US 2011/0033621 A1
(43) Pub. Date: Feb. 10, 2011

(54) THIN FILM DEPOSITION APPARATUS INCLUDING DEPOSITION BLADE

(75) Inventors: Choong-Ho Lee, Yongin-city (KR); Jung-Min Lee, Yongin-city (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Yongin-city (KR)

(21) Appl. No.: 12/849,092

(22) Filed: Aug. 3, 2010

(30) Foreign Application Priority Data
Aug. 10, 2009 (KR) 10-2009-0073524
Feb. 17, 2010 (KR) 10-2010-0014273

(51) Int. Cl. C23C 16/04; C23C 16/44

(52) U.S. Cl. 427/248.1; 118/720

(57) ABSTRACT

A thin film deposition apparatus for use with a substrate having deposition regions separated by non-deposition regions includes a deposition source, a first nozzle assembly disposed in front of the deposition source, at least one barrier wall assembly disposed in front of the first nozzle assembly, and a second nozzle assembly disposed between the barrier wall assembly and the substrate. At least one deposition blade is disposed between the deposition source and the first nozzle assembly, the first nozzle assembly and the barrier wall assembly, the barrier wall assembly and the second nozzle assembly, or the second nozzle assembly and the substrate. Using the deposition blade, the deposition of the deposition material on the non-deposition regions of the substrate may be minimized during a deposition process.

### CROSS-REFERENCE TO RELATED APPLICATIONS

This application claims the benefit of Korean Patent Application No. 10-2009-0073524, filed Aug. 10, 2009 in the Korean Intellectual Property Office and Korean Patent Application No 10-2010-0014273, filed Feb. 17, 2010 in the Korean Intellectual Property Office, the disclosures of which are incorporated herein by reference.

### BACKGROUND

1. Field

Aspects of the present invention relate to a thin film deposition apparatus, and more particularly, to a thin film deposition apparatus including a deposition blade so that a deposition material is not deposited on non-deposition regions of a substrate.

2. Description of the Related Art

Organic light-emitting display devices are self-emitting displays which are driven at a low voltage, are thin, and have a wide viewing angle and a quick response rate. Organic light-emitting display devices include an anode, a cathode, and an emission layer interposed between the anode and the cathode. The devices display images in color when holes and electrons, injected respectively from the anode and the cathode, recombine in the emission layer and thus light is emitted.

However, it is difficult to achieve high light-emission efficiency with such a structure. Therefore, intermediate layers are optionally interposed between the emission layer and each of the electrodes. The intermediate layer can include an electron injection layer, an electron transport layer, a hole injection layer, or the like.

It is practically very difficult to form fine patterns in organic thin films such as the emission layer and the intermediate layers. Moreover, red, green, and blue light-emission efficiencies vary according to the organic thin films. For these reasons, it is not easy to form an organic thin film pattern on a large substrate, such as a mother glass, by using a conventional thin film deposition apparatus. Thus, it is difficult to manufacture large organic light-emitting display devices having satisfactory driving voltage, current density, brightness, color purity, light-emission efficiency, and life-span characteristics. Therefore, there is a demand for improvement in this regard.

The anode, cathode, emission layer, and intermediate layer may be formed using a variety of methods, one of which is a deposition method. When an organic light-emitting display device is manufactured using the deposition method, a fine metal mask (FMM) is used. The FMM has the same pattern as a thin layer to be formed on a substrate. The FMM is disposed to closely contact the substrate, and a thin film material is deposited over the FMM to form the thin layer having the desired pattern. Thus, the size of the FMM has to be increased as the substrate becomes larger. However, it is neither straightforward to manufacture a large FMM and develop a large-sized deposition source, nor to extend an FMM to be accurately aligned with a pattern.

Furthermore, a conventional FMM deposition method has a low deposition efficiency. Deposition efficiency refers to the ratio of a deposition material deposited on a substrate to the deposition material vaporized from a deposition source. The conventional FMM deposition method has a deposition efficiency of about 32%. Furthermore, in the conventional FMM deposition method, about 68% of organic deposition material that is not deposited on the substrate remains adhered to undesirable regions in a thin film deposition apparatus, and thus reusing the deposition material is not straightforward.

### SUMMARY

Aspects of the present invention provide a thin film deposition apparatus including a deposition blade, by which a deposition material is easily deposited on a substrate with high deposition efficiency.

Aspects of the present invention provide a thin film deposition apparatus including a deposition blade, by which a deposition material is not deposited on a non-deposition region of a substrate.

According to an aspect of the present invention, there is provided a thin film deposition apparatus including a deposition blade, the thin film deposition apparatus including: a substrate having a plurality of deposition regions and a plurality of non-deposition regions formed between the deposition regions to partition the deposition regions; and a thin film deposition apparatus including a deposition source, a first nozzle assembly disposed in front of the deposition source, at least one barrier wall assembly disposed in front of the first nozzle assembly, and a second nozzle assembly disposed between the barrier wall assembly and the substrate, wherein spaces are formed between each two adjacent units selected from the group consisting of the deposition source, the first nozzle assembly, the barrier wall assembly, the second nozzle assembly, and the substrate, and at least one deposition blade is disposed in one of the spaces corresponding to non-deposition regions of the substrate.

According to an aspect of the present invention, the deposition source may be disposed opposite to the substrate and includes a deposition material that is vaporized, the first nozzle assembly may include a first nozzle that includes a plurality of first slits arranged in a first direction of the substrate and a first nozzle frame that supports the first nozzle, the barrier wall assembly may include a plurality of barrier walls arranged between the first nozzle assembly and the second nozzle assembly to partition the space between the first nozzle assembly and the second nozzle assembly; and the second nozzle assembly may include a second nozzle that includes a plurality of second slits arranged in the first direction of the substrate and a second nozzle frame that supports the second nozzle.

According to an aspect of the present invention, the non-deposition region may include first non-deposition regions formed along the first direction of the substrate between the deposition regions which are arranged to be spaced apart from each other in the second direction of the substrate perpendicular to the first direction, and second non-deposition regions formed along the second direction of the substrate between the deposition regions which are arranged to be spaced apart from each other in the first direction, and the plurality of deposition blades may respectively cover regions corresponding to first non-deposition regions while the deposition material is deposited.

According to an aspect of the present invention, the width of each of the deposition blades may be substantially the same as the width of the first non-deposition regions.

According to an aspect of the present invention, the second nozzle assembly may further cover the regions corresponding to the second non-deposition regions when the thin film deposition apparatus is moved up and down.

According to an aspect of the present invention, the deposition blades may further cover regions corresponding to the second non-deposition regions while the deposition material is deposited.

According to an aspect of the present invention, the barrier wall assembly may include a first barrier wall assembly disposed between the first nozzle assembly and the second nozzle assembly and a second barrier wall assembly disposed between the first barrier wall assembly and the second nozzle assembly, and the deposition blade may be disposed in the space between the first barrier wall assembly and the second barrier wall assembly.

According to an aspect of the present invention, the deposition blade may be disposed in the space between the deposition source and the barrier wall assembly.

According to another aspect of the present invention, there is provided a thin film deposition apparatus including a deposition blade for depositing a deposition material on a substrate, the thin film deposition apparatus including: a thin film deposition apparatus including a deposition source, a first nozzle assembly disposed in front of the deposition source, at least one barrier wall assembly disposed in front of the first nozzle assembly, and a second nozzle assembly disposed between the barrier wall assembly and the substrate; and a vacuum chamber including the deposition source, the first nozzle assembly, the barrier wall assembly, the second nozzle assembly, and the substrate, wherein a deposition blade is connected to the vacuum chamber, spaces are formed between each two adjacent units selected from the group consisting of the deposition source, the first nozzle assembly, the barrier wall assembly, the second nozzle assembly, and the substrate, and the deposition blade is optionally disposed in one of the spaces when the thin film deposition apparatus is moved up and down to an upper or lower portion of the vacuum chamber during a stand-by mode.

According to an aspect of the present invention, the deposition source may be disposed opposite to the substrate and includes a deposition material that is vaporized, the first nozzle assembly may include a first nozzle that includes a plurality of first slits arranged in a first direction of the substrate, the barrier wall assembly may include a plurality of barrier walls arranged between the first nozzle assembly and the second nozzle assembly to partition the space between the first nozzle assembly and the second nozzle assembly, and the second nozzle assembly may include a second nozzle that includes a plurality of second slits arranged in the first direction of the substrate.

According to an aspect of the present invention, the deposition blade may include a first deposition blade that is fixed to an upper portion of the vacuum chamber and a second deposition blade that is fixed to a lower portion of the vacuum chamber, wherein the thin film deposition apparatus is disposed between the first and second deposition blades.

According to an aspect of the present invention, the barrier wall assembly may include a first barrier wall assembly disposed between the first nozzle assembly and the second nozzle assembly and a second barrier wall assembly disposed between the first barrier wall assembly and the second nozzle assembly, and the deposition blade may be disposed in the space between the first barrier wall assembly and the second barrier wall assembly at an upper or lower portion of the vacuum chamber.

According to an aspect of the present invention, the first barrier wall assembly may include a plurality of first barrier walls arranged to be spaced apart from each other in the first direction of the substrate, wherein each of the first barrier walls is formed to extend along the second direction of the substrate perpendicular to the first direction, the second barrier wall assembly includes a plurality of second barrier walls arranged to be spaced apart from each other in the first direction of the substrate, wherein each of the second barrier walls is formed to extend along the second direction perpendicular to the first direction, and the second barrier walls are respectively disposed to be parallel to and to be on the same plane as the first barrier walls with respect to the substrate to partition the space between the first nozzle assembly and the second nozzle assembly.

According to an aspect of the present invention, the deposition blade may be disposed in the space between the deposition source and the barrier wall assembly at an upper or lower portion of the vacuum chamber.

According to another aspect of the present invention, there is provided a thin film deposition apparatus including a deposition blade for forming a thin film on a substrate that includes a plurality of deposition regions and a plurality of non-deposition regions formed between the deposition regions to partition the deposition regions, the thin film deposition apparatus including: a deposition source that discharges a deposition material; a first nozzle disposed at a side of the deposition source and including a plurality of first slits arranged in a first direction; and a second nozzle disposed opposite to the first nozzle and including a plurality of second slits arranged in a second direction perpendicular to the first direction, wherein at least one space is formed between the deposition source and the first nozzle, between the first nozzle and the second nozzle, and between the second nozzle and the substrate, a deposition blade is disposed in at least one of the spaces corresponding to non-deposition regions of the substrate, and a deposition is performed while the substrate moves relative to the thin film deposition apparatus in the first direction.

According to an aspect of the present invention, the non-deposition region may include first non-deposition regions formed along the second direction between the plurality of deposition regions which are arranged to be spaced apart from each other in the first direction, and second non-deposition regions formed along the first direction between the plurality of deposition regions which are arranged to be spaced apart from each other in the second direction, and the deposition blades may be disposed at regions corresponding to the first non-deposition regions while the deposition material is deposited.

According to an aspect of the present invention, the width of each of the deposition blades may be substantially the same as the width of the first non-deposition regions.

According to an aspect of the present invention, the deposition blades may be formed to further cover regions corresponding to the second non-deposition regions while the deposition material is deposited.

According to an aspect of the present invention, the deposition blade may be disposed in the space between the substrate and the second nozzle.

According to an aspect of the present invention, the thickness of the deposition blade may be less than the distance between the substrate and the second nozzle to be disposed between the substrate and the second nozzle.

According to an aspect of the present invention, the thin film deposition apparatus may be disposed in a vacuum chamber, and the deposition blade may be connected to the vacuum chamber.

According to an aspect of the present invention, the deposition blade may be connected to the vacuum chamber to be optionally disposed in one of the spaces when the thin film deposition apparatus is moved to a side of the vacuum chamber during a stand-by mode.

According to an aspect of the present invention, the deposition source and the first nozzle, and the second nozzle may be connected to each other by a connection member.

According to an aspect of the present invention, the connection member may guide movement of the discharged deposition material.

According to an aspect of the present invention, the connection member may seal the space between the deposition source and the first nozzle, and the second nozzle.

According to an aspect of the present invention, the thin film deposition apparatus may be separated from the substrate by a predetermined distance.

According to an aspect of the present invention, the deposition material discharged from the thin film deposition apparatus may be continuously deposited on the substrate while the substrate is moved relative to the thin film deposition apparatus in the first direction.

According to an aspect of the present invention, the second nozzle of the thin film deposition apparatus may be smaller than the substrate.

According to an aspect of the present invention, the plurality of first slits may be tilted at a predetermined angle.

According to an aspect of the present invention, the plurality of first slits may include first slits arranged in two rows formed in the first direction, and the first slits in the two rows may be tilted to face each other.

According to an aspect of the present invention, the plurality of first slits may include first slits arranged in two rows formed in the first direction, wherein the first slits arranged in a row located at a first side are arranged to face a second side of the second nozzle, and the first slits arranged in the other row located at a second side are arranged to face the first side of the second nozzle.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic perspective view of a thin film deposition apparatus according to an embodiment of the present invention;

FIG. 2 is a schematic side view of the thin film deposition apparatus of FIG. 1;

FIG. 3 is a schematic plan view of the thin film deposition apparatus of FIG. 1;

FIG. 4 is a schematic front view of the thin film deposition apparatus of FIG. 1;

FIG. 5 is a schematic side view of a thin film deposition apparatus according to another embodiment of the present invention;

FIG. 6 is a schematic side view of a thin film deposition apparatus according to another embodiment of the present invention;

FIG. 7 is a schematic side view of a thin film deposition apparatus according to another embodiment of the present invention;

FIG. 8 is a schematic perspective view of a thin film deposition apparatus according to another embodiment of the present invention;

FIG. 9 is a schematic side view of the thin film deposition apparatus of FIG. 8;

FIG. 10 is a schematic plan view of the thin film deposition apparatus of FIG. 8;

FIG. 11 is a schematic perspective view of a thin film deposition apparatus according to another embodiment of the present invention;

FIG. 12 is a graph schematically illustrating a distribution pattern of a deposition layer formed on a substrate when first slits are not tilted, in a thin film deposition apparatus according to an embodiment of the present invention;

FIG. 13 is a graph schematically illustrating a distribution pattern of a deposition layer formed on a substrate when first slits are tilted, in a thin film deposition apparatus according to an embodiment of the present invention; and

FIG. 14 is a schematic side view of a thin film deposition apparatus according to another embodiment of the present invention.

### DETAILED DESCRIPTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

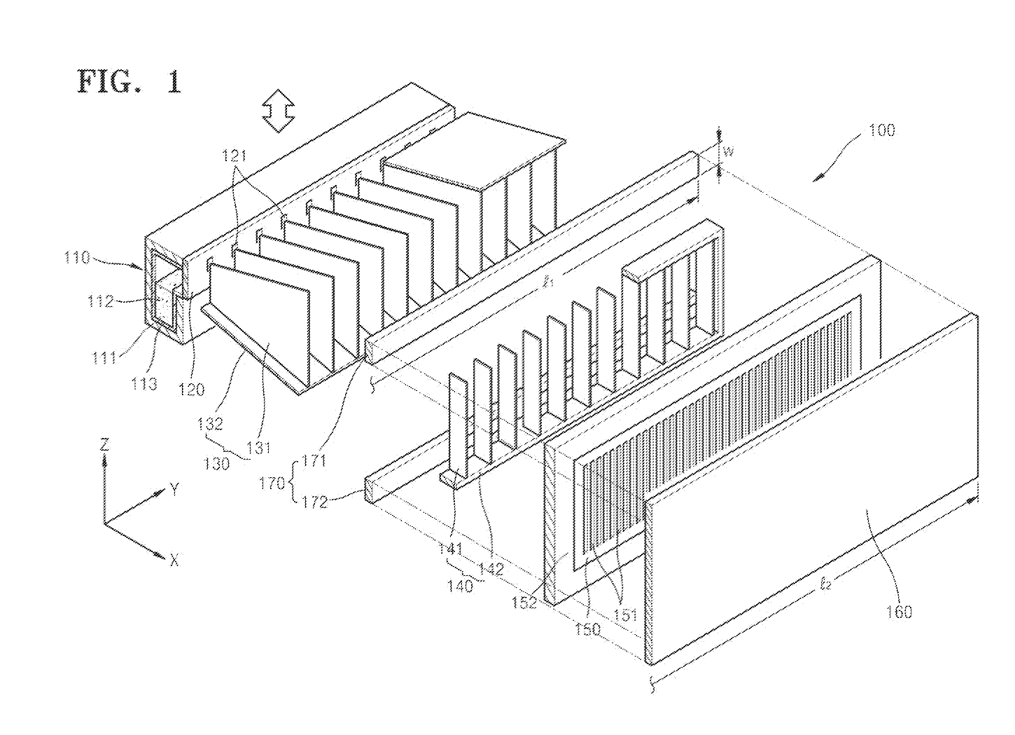

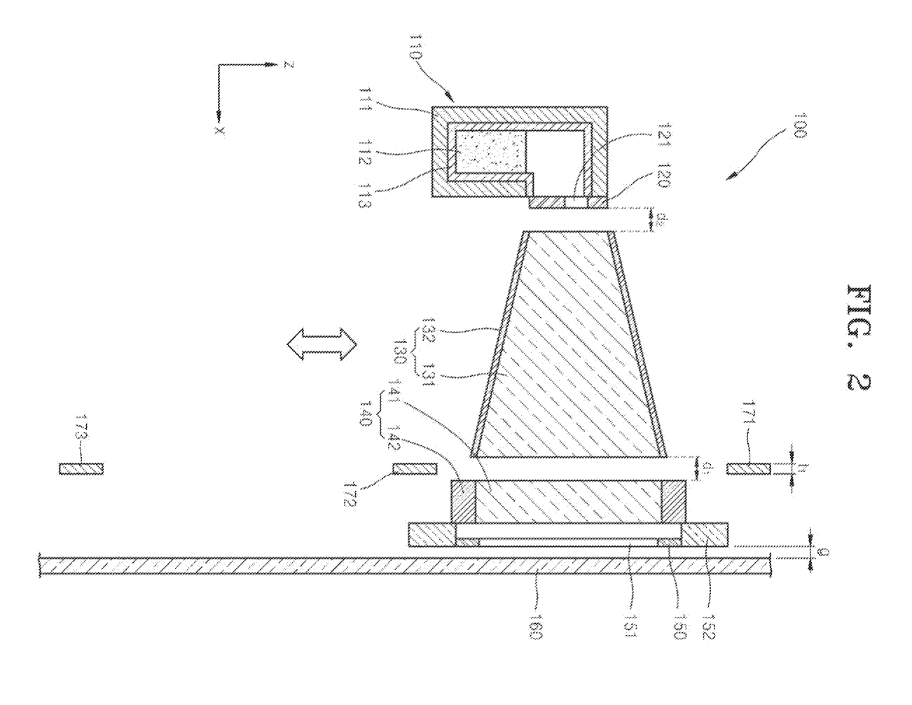

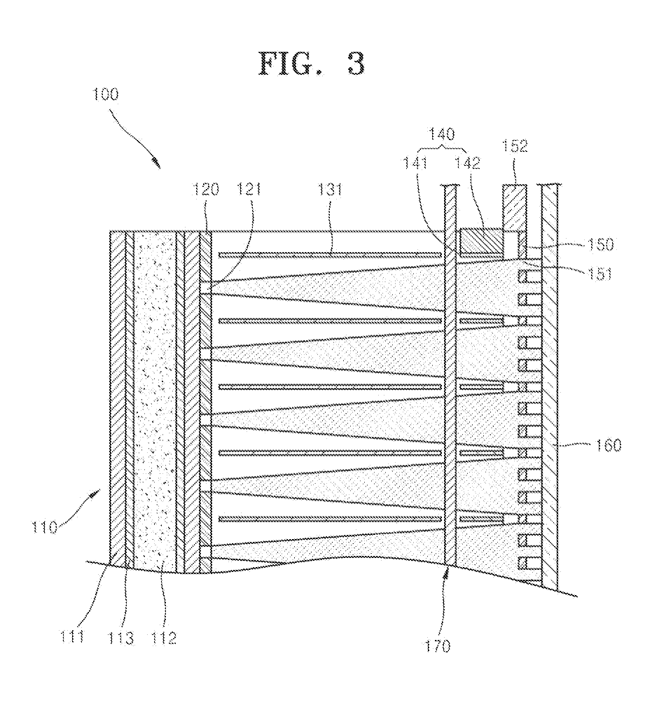

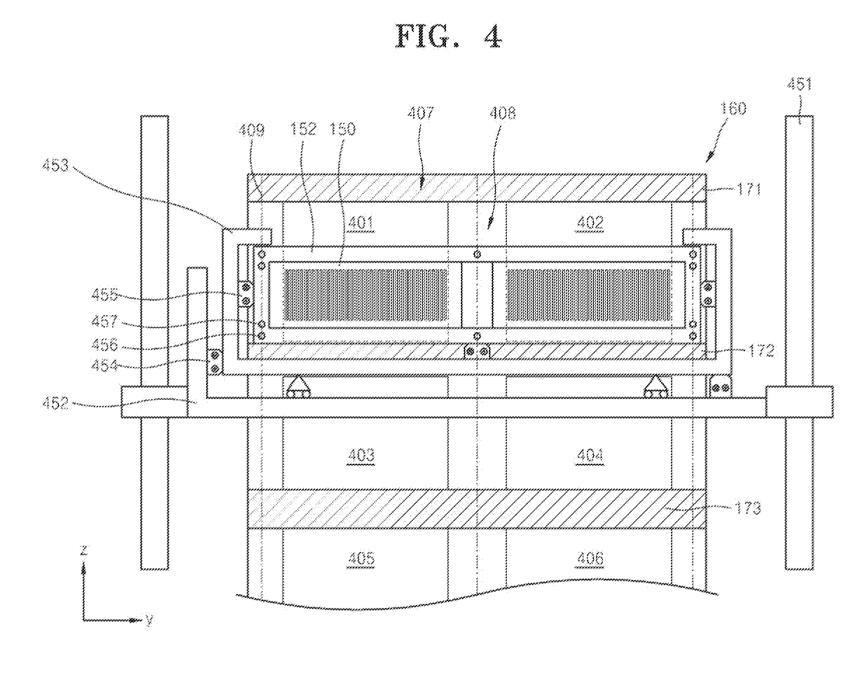

FIG. 1 is a schematic perspective view of a thin film deposition apparatus 100 according to an embodiment of the present invention, FIG. 2 is a schematic side view of the thin film deposition apparatus 100 of FIG. 1, FIG. 3 is a schematic plan view of the thin film deposition apparatus 100 of FIG. 1, and FIG. 4 is a schematic front view of the thin film deposition apparatus 100 of FIG. 1. Referring to FIGS. 1 to 4, the thin film deposition apparatus 100 includes a deposition source 110, a first nozzle 120, a first barrier wall assembly 130, a second barrier wall assembly 140, a second nozzle 150, and a substrate 160. The first nozzle 120 is disposed in front of the deposition source 110. The first barrier wall assembly 130 is disposed in front of the first nozzle 120. The second barrier wall assembly 140 is disposed in front of the first barrier wall assembly 130. The second nozzle 150 is disposed in front of the second barrier wall assembly 140. The substrate 160 is disposed in front of the second nozzle 150. A vacuum chamber 460 surrounds the thin film deposition apparatus 100 and the substrate 160.

The deposition source 110 includes a heat resistant crucible 111. The crucible 111 is filled with a deposition material 112 to be deposited on the substrate 160. A heater 113 vaporizes the deposition material 112 and is disposed on the inner surface of the crucible 111.

The first nozzle 120 is disposed in front of the deposition source 110 (i.e., at a side of the deposition source 110 facing the substrate 160 in the X-axis direction). The first nozzle 120 includes a plurality of first slits 121 arranged at equal intervals. The first slits 121 are arranged along the Y axis direction of the substrate 160. The deposition material 112 that is vaporized in the deposition source 110 proceeds toward the substrate 160 via the first slits 121.

The first barrier wall assembly 130 is disposed in front of the first nozzle 120. The first barrier wall assembly 130 includes a plurality of first barrier walls 131. The first barrier walls 131 are arranged parallel to each other at equal intervals in a first direction (i.e., the Y-axis direction) of the substrate 160. Each of the first barrier walls 131 extends along a second direction (i.e., parallel to an XZ plane) and perpendicular to the first direction. However, the invention is limited to the specific shown orientation of the first barrier walls 131.

The first barrier walls 131 are respectively disposed between adjacent first slits 121. In order words, each of the first slits 121 is disposed between two adjacent first barrier walls 131. The first slits 121 can respectively located at the midpoint of the first nozzle 120 between two adjacent first barrier walls 131. However, the invention is not specifically limited thereto.

A first barrier wall frame 132 is formed to surround the first barrier walls 131. The first barrier wall frame 132 forms upper and lower outer walls surrounding the first barrier walls 131 and retains the positions of the first barrier walls 131.

The second barrier wall assembly 140 is disposed in front of the first barrier wall assembly 130 to be parallel to the first barrier wall assembly 140. The second barrier wall assembly 140 includes a plurality of second barrier walls 141. The second barrier walls 141 are arranged parallel to each other at equal intervals in the first direction of the substrate 160. Each of the second barrier walls 141 may be formed to extend along the second direction (i.e., parallel to the XZ plane) and perpendicular to the first direction. However, the invention is not specifically limited to the specific shown orientation of the second barrier walls 141.

Since the second barrier walls 141 should be precisely aligned with the second nozzle 150, respectively, each of the second barrier walls 141 is formed to be relatively thinner than each of the first barrier walls 131. In contrast, the first barrier walls 131 do not need to be precisely aligned with the second nozzle 150. Thus, the first barrier walls 131 may be formed to be relatively thick. This makes it easier to manufacture the first barrier walls 131. However, it is understood that the walls 131, 141 can have a uniform thickness in other aspects.

A second barrier wall frame 142 surrounds the second barrier walls 141. The second barrier wall frame 142 forms upper and lower outer walls surrounding the second barrier walls 141 and retains the positions of the second barrier walls 141.

The second barrier walls 141 are disposed to correspond to the first barrier walls 131. In other words, the second barrier walls 141 are respectively disposed to be on the same plane as the first barrier walls 131 in the X-axis direction. The second barrier walls 141 may be respectively disposed to be parallel to and to be on the same plane as the first barrier walls 131 in the second direction that is perpendicular to the first direction of the substrate 160 to partition the space between the first nozzle 120 and the second nozzle 150. Accordingly, the deposition material 112 discharged through one first slit 121 is not mixed with the deposition material 112 discharged through another first slit 121, and is deposited on the substrate 160 through the second slits 151 of the second nozzle 150.

As such, the thin film deposition apparatus 100 has a deposition space that is enclosed by the first barrier wall assembly 130 and the second barrier wall assembly 140. The deposition material 112 that remains undeposited is mostly deposited within the first barrier wall assembly 130 and partially deposited within the second barrier wall assembly 140. Thus, when a large amount of the deposition material 112 lies in the first barrier wall assembly 130 after a long deposition process, the first barrier wall assembly 130 may be detached from the thin film deposition apparatus 100 and then placed in a separate deposition material recycling apparatus to recover the deposition material 112.

In addition, the first barrier wall assembly 130 and the second barrier wall assembly 140 are separated from each other by a predetermined distance. The first barrier wall assembly 130 and the second barrier wall assembly 140 are separated from each other since the second barrier walls 141 and the second nozzle 150 should be precisely aligned with each other. In contrast, it is unnecessary to precisely align the first barrier walls 131 and the second barrier walls 141. Thus, high-precision control may be easily achieved by separating a part required to be precisely controlled from a part not required to be precisely controlled.

Furthermore, the temperature of the first barrier wall assembly 130 may increase to 100° C. or higher due to the high temperature of the deposition source 110. In order to prevent the heat of the first barrier wall assembly 130 from being conducted to the second barrier wall assembly 140 and the second nozzle 150, the first barrier wall assembly 130 and the second barrier wall assembly 140 are separated from each other.

In the thin film deposition apparatus 100, the deposition material 112 adhered to the first barrier wall assembly 130 is mostly reused. In contrast, the deposition material 112 adhered to the second barrier wall assembly 140 and the second nozzle 150 may not easily be reused. Thus, when the first barrier wall assembly 130 is separated from the second barrier wall assembly 140 and the second nozzle 150, it may be straightforward to recover the deposition material 112 to be reused.

The second nozzle 150 is disposed between the second barrier wall assembly 140 and the substrate 160. The second nozzle 150 includes a plurality of second slits 151 arranged at equal intervals in the Y-axis direction. The second slits 151 are arranged along the first direction of the substrate 160 and are elongated in the Z-axis direction. A second nozzle frame 152 is formed to retain the position of the second nozzle 150.

In this regard, a total number of the second slits 151 of the second nozzle 150 is greater than a total number of the first slits 121 of the first nozzle 120. In addition, the number of the second slits 151 disposed between two adjacent first and second barrier walls 131 and 141 may be greater than the number of the first slits 121 disposed between the two adjacent first and second barrier walls 131 and 141. Although one first slit 121 corresponds to three second slits 151 between two adjacent first and second barrier walls 131 and 141 in FIGS. 1 to 4, the number of the second slits 151 corresponding to one first slit 121 may vary.

The second nozzle 150 and the substrate 160 are separated from each other by a predetermined distance. Accordingly, a defect caused by the contact between the second nozzle 150 and the substrate 160 may be prevented. This may be implemented by installing the first barrier wall assembly 130 and the second barrier wall assembly 140 to reduce the width of the shadow zone formed on the substrate 160.

In addition, deposition is performed while the thin film deposition apparatus 100 is moved up and down relative to the substrate 160 in the Z-axis direction. Thus, the size of the second nozzle 150 in the first direction of the substrate 160 is enough to cover one deposition region on the substrate 160 that will be described later, whereas the size of the second nozzle 150 in the second direction of the substrate 160 is smaller than the deposition region.

The substrate 160 may be a substrate for flat panel displays. A large substrate, such as a mother glass, for manufacturing a plurality of flat panel displays, may be used as the substrate 160. The substrate 160 is disposed on an opposite side of the deposition source 110 in the X-axis direction. The first nozzle 120, the first barrier wall assembly 130, the second barrier wall assembly 140, and the second nozzle 150 are disposed between the substrate 160 and the deposition source 110.

The thin film deposition apparatus 100 including the deposition source 110, the first nozzle 120, the first barrier wall assembly 130, the second barrier wall assembly 140, the second nozzle 150, and substrate 160 may be disposed in the vacuum chamber 460 in order to allow a deposition material 112 to move straight. However, it is understood that the vacuum chamber need not be used in all aspects, and/or that the chamber need not achieve a perfect vacuum in all circumstances.

In addition, the temperatures of the first barrier wall assembly 130, the second barrier wall assembly 140 and the second nozzle 150 should be sufficiently lower than the temperature of the deposition source 110. In this regard, the temperatures of the first barrier wall assembly 130, the second barrier wall assembly 140 and the second nozzle 150 may be about 100° C. or less, so that the space between the first nozzle 120 and the second nozzle 150 may be maintained at a high vacuum. As such, if the temperatures of the first barrier wall assembly 130, the second barrier wall assembly 140 and the second nozzle 150 are sufficiently lower than the temperature of the deposition source 110, the deposition material 112 that collided against the first barrier wall assembly 130 and the second barrier wall assembly 140 may not be vaporized again, thereby maintaining the chamber at a high vacuum. Thus, since the deposition materials 112 do not collide with each other, the deposition materials 112 may move straight.

In this regard, as shown in FIG. 4, a plurality of deposition regions 401 to 406 are formed on the substrate 160 in order to simultaneously manufacture a plurality of flat panel display devices using the large-sized substrate 160. Each of the deposition regions 401 to 406 may correspond to each of the flat panel display devices, although the invention is not limited thereto.

The deposition regions 401 to 406 are spaced apart from each other by a predetermined distance on the entire substrate 160. The deposition material 112 discharged from the deposition source 110 is deposited on the deposition regions 401 to 406. Although six deposition regions 401 to 406 are shown in FIG. 4, the number of the deposition regions 401 to 406 may vary according to the size of the substrate 160.

First and second non-deposition regions 407 and 408 are disposed between edges of the deposition regions 401 to 406. The deposition material 112 is not deposited on the first and second non-deposition regions 407 and 408, and the first non-deposition regions 407 are formed in the first direction of the substrate 160 and the second non-deposition regions 408 are formed in the second direction of the substrate 160.

In other word, the first non-deposition regions 407 are formed along the first direction of the substrate 160 to partition the space between the deposition regions 401 to 406 which are spaced apart from each other in the second direction of the substrate 160 perpendicular to the first direction. The second non-deposition regions 408 are formed along the second direction of the substrate 160 to partition the space between the deposition regions 401 to 406 which are spaced apart from each other in the first direction of the substrate 160. The first non-deposition regions 407 and the second non-deposition regions 408 are connected to each other in a lattice shape in the shown embodiment, although the invention is not limited thereto.

The first non-deposition regions 407 and the second non-deposition regions 408 are connected to each other. Thus, each of the deposition regions 401 to 406 is surrounded by the first non-deposition regions 407 and the second non-deposition regions 408 to be independently disposed.

In addition, the substrate 160 includes positioning marks 409. The positioning marks 409 are used as reference marks to maintain the interval between the second nozzle 150 and the substrate 160 constant and to precisely align the second nozzle 150 and the substrate 160 with respect to each other. Although the positioning marks 409 are respectively formed in a left edge region, a central region, a right edge region of the substrate 160 as illustrated in FIG. 4, the present invention is not limited thereto.

Rails 451 are disposed on opposite sides of the substrate 160. The base frame 452 is inserted between the rails 451. The base frame 452 is moved up and down in the Z-axis direction along the rails 451 due to a driving force of a driving motor.

All the elements of the thin film deposition apparatus 100 that are involved in maintaining a constant interval between the second nozzle 150 and the substrate 160 and in precisely aligning the second nozzle 150 and the substrate 160 with respect to each other are disposed on the base frame 452. As shown, the second nozzle 150, the second nozzle frame 152, a tray 453, an interval adjusting member, and an alignment adjusting member are disposed on the base frame 452.

The tray 453 is mounted on the base frame 452. The second nozzle frame 152 is installed in the tray 453 to be detachable from the tray 453. In addition, the interval adjusting member is disposed between the tray 453 and the second nozzle frame 152. The alignment adjusting member is disposed between the base frame 452 and the tray 453.

The tray 453 fixes the second nozzle frame 152 such that the second nozzle frame 152 is prevented from moving in the Y-axis and Z-axis directions but is movable to some extent in the X-axis direction within the tray 453. In other words, the interval between the substrate 160 and the second nozzle 150 may be adjusted by moving the second nozzle frame 152 relative to the tray 453 in the X-axis direction.

The tray 453 may be moved relative to the base frame 452 in the Y-axis and Z-axis directions by an alignment adjusting actuator 454. However, the tray 453 is fixed to not move in the X-axis direction. In other words, the second nozzle 150 and the substrate 160 may be precisely aligned with each other in the Y-axis and Z-axis directions by moving the tray 453 relative to the base frame 451 along an YZ plane.

The interval adjusting member includes a plurality of interval adjusting actuators 455 and a plurality of interval adjusting sensors 456. The interval adjusting actuator 455 is disposed between the tray 453 and the second nozzle frame 152 to control the interval between the second nozzle 150 and the substrate 160. The interval adjusting sensor 456 is mounted on the second nozzle frame 152 to measure the interval between the second nozzle frame 152 and the substrate 160. Herein, the interval adjusting sensor 456 may measure the interval between the second nozzle frame 152 and the substrate 160 by using the positioning marks 409 on the substrate 160.

The alignment adjusting member includes a plurality of alignment adjusting actuators 454 and a plurality of alignment adjusting sensors 457. The alignment adjusting actuators 454 may be disposed between the base frame 452 and the tray 453 to control rotation angles of the tray 453 and the second nozzle 150, which is installed in the tray 453, with respect to the substrate 160, and thus to adjust alignment between the second nozzle 150 and the substrate 160. The alignment adjusting sensors 457 are mounted on the second nozzle frame 152 to measure whether the second nozzle frame 152 and the substrate 160 are aligned with each other. The alignment adjusting sensors 457 may measure whether the second nozzle frame 152 and the substrate 160 are aligned with each other, by using the positioning marks 409 on the substrate 160. While shown with two sets of sensors 456, 457, it is understood that only a single set of sensors could be used by both the alignment control member and the interval control member.

In this regard, an open mask (not shown) may be used in order to deposit the deposition material 112 on the deposition regions 401 to 406 not to deposit the deposition material 112 on the first and second non-deposition regions 407 and 408 while the deposition material 112 is deposited on the substrate 160. The open mask has openings respectively corresponding to the deposition regions 401 to 406 and does not have openings in regions corresponding to the first and second non-deposition regions 407 and 408. A deposition process is performed by disposing the open mask on the substrate 160 facing the second nozzle 150. However, it is difficult to constantly maintaining a desirable gap (g), e.g., 100 μm, between the second nozzle 150 and the substrate 160 when using the open mask.

Accordingly, a plurality of deposition blades 170 may be disposed in any space formed between elements of the thin film deposition apparatus 100. Examples of such elements include the first nozzle 120, the first barrier wall assembly 130, the second barrier wall assembly 140, the second nozzle 150, and the substrate 160 instead of using the open mask.

The deposition blades 170 are disposed in the space (d1) between the first barrier wall assembly 130 and the second barrier wall assembly 140. For this, the thickness (t1) of the deposition blades 170 is less than the distance (d1) between the first barrier wall assembly 130 and the second barrier wall assembly 140 to be disposed between the first barrier wall assembly 130 and the second barrier wall assembly 140. The deposition blades 170 may be formed of a thin metal film, but the invention is not limited thereto.

The deposition blades 170 are formed to cover regions corresponding to the first non-deposition regions 407 that partition the space between the deposition regions 401 to 406. The deposition regions 401 to 406 are spaced apart from each other in the second direction of the substrate 160. In other words, the deposition blades 170 are respectively disposed along the first direction of the substrate 160 and separate regions 401 to 406 which are adjacent in the Z-axis direction.

The deposition blades 170 may include a first to an n^{th} deposition blades to cover all of the first non-deposition regions 407 formed on the substrate 160. Even though three deposition blades 171, 172, and 173 are shown in FIG. 4, the number of the deposition blades 170 may vary according to the number of the first non-deposition regions 407 formed on the substrate 160.

While not required in all aspects, the width W of each of the deposition blades 171, 172, and 173 is formed to be substantially the same as the width of the first non-deposition regions 407 so as to completely cover the first non-deposition regions 407. The length (l1) of the deposition blades 171, 172, and 173 may also be greater than the length (l2) of the substrate 160 in the first direction. In this regard, the deposition blades 171, 172, and 173 are respectively flat with a strip shape. However, it is understood that the deposition blades 171, 172, and 173 need not be flat or strip shaped, and further need not have the same shape in all aspects of the invention.

The deposition blades 170 do not cover regions corresponding to the second non-deposition regions 408 that partition the space between the deposition regions 401 to 406 which are arranged to be spaced apart from each other in the first direction of the substrate 160. In other words, the deposition blades 170 are not disposed along the second direction of the substrate 160. This is because the second nozzle frame 152 includes the second nozzle 150 and moves up and down. The second nozzle frame 152 may prevent the deposition material 112 vaporized in the deposition source 110 from being deposited on the second non-deposition regions 408 of the substrate 160 during the deposition process. In other words, the second nozzle frame 152 covers the regions corresponding to the second non-deposition regions 408 such that additionally blades need not be used.

Alternatively, the deposition blades 170 may also be optionally disposed in the second direction of the substrate 160 as well as the first direction of the substrate 160, or a plurality of deposition blades that are disposed in the first and second directions of the substrate 160 may be connected to each other or independently disposed. Any other structure in which the deposition blades 170 cover the first and second non-deposition regions 407 and 408 except for the deposition regions 401 to 406 may also be used without limitation.

In addition, the deposition blades 170 may be connected to a separate frame 462 installed in the vacuum chamber 460 to position the deposition blades 170, or may be disposed in the space between the first barrier wall assembly 130 and the second barrier wall assembly 140 to simultaneously move up and down together with the thin film deposition apparatus 100 to cover the first and second non-deposition regions 407 and 408 with the second nozzle frame 152 including the second nozzle 150.

A deposition process of the thin film deposition apparatus 100 having the structure described above will be described. The deposition material 112 is vaporized in the deposition source 110 are discharged through the first slits 121 of the first nozzle 120. The discharged deposition material 112 proceeds through the space partitioned by the first barrier wall assembly 130 and the second barrier wall assembly 140. The deposition material 112 is deposited on the deposition regions 401 to 406 of the substrate 160 through the second slits 151 of the second nozzle 150.

Since the space between the first nozzle 120 and the second nozzle 150 is partitioned by the first barrier walls 131 and the second barrier walls 141, the deposition material 112 discharged through one first slit 121 of the first nozzle 120 is not mixed with the deposition material 112 discharged through another adjacent first slit 121 due to the first barrier walls 131 and the second barrier walls 141.

When the space between the first nozzle 120 and the second nozzle 150 is partitioned by the first barrier walls 131 and the second barrier walls 141, the deposition material 112 is deposited on the substrate 160 through the second nozzle 150 at an angle that is substantially perpendicular to the substrate 160. In this regard, the deposition material 112 is not deposited on the first non-deposition regions 407 that are formed to be spaced apart from each other in the first direction of the substrate 160 by each of the deposition blades 171, 172, and 173 disposed in the space between the first barrier wall assembly 130 and the second barrier wall assembly 140. The deposition material 112 is not deposited on the second non-deposition regions 408 that are formed along the second direction of the substrate 160 by the second nozzle frame 152 including the second nozzle 150 moving up and down, either.

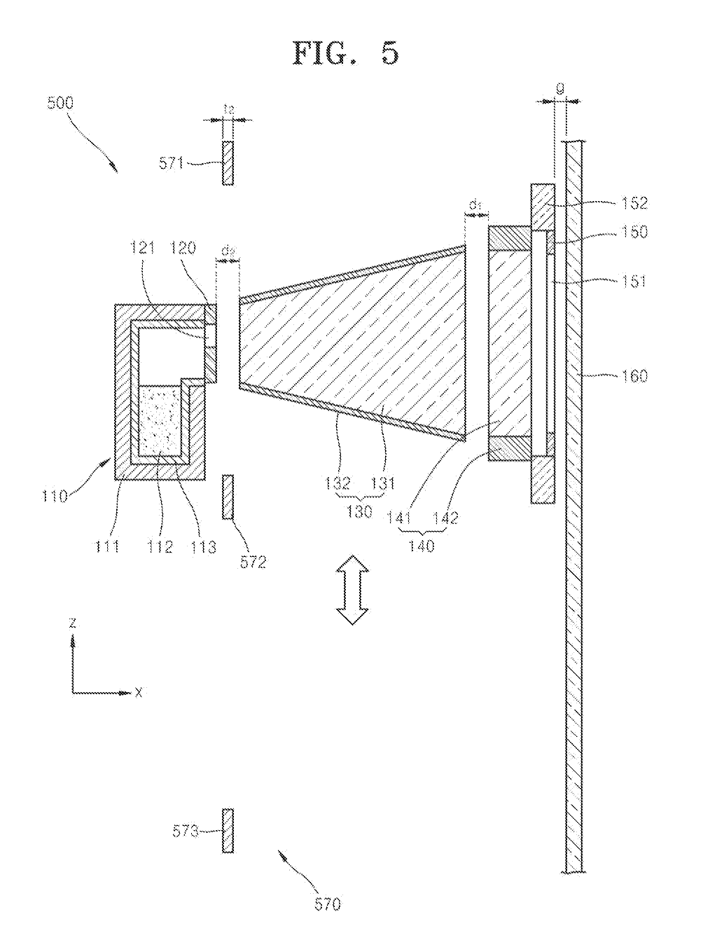

FIG. 5 is a schematic side view of a thin film deposition apparatus 500 according to another embodiment of the present invention. Like elements having same reference numerals described above in relation to FIGS. 1 to 4 have same functions, and thus descriptions thereof will not be repeated. Referring to FIG. 5, deposition blades 570 are disposed in the thin film deposition apparatus 500. The deposition blades 570 are disposed in the space (d2) between the deposition source 110 and the first barrier wall assembly 130. For this, the thickness (t2) of the deposition blades 570 is less than the distance (d2) between the deposition source 110 and the first barrier wall assembly 130 to be disposed between the deposition source 110 and the first barrier wall assembly 130. The deposition blades 570 may be formed of a thin metal film, but the invention is not limited thereto.

The deposition blades 570 are disposed at a position corresponding to the non-deposition region 407 formed at edges of a plurality of deposition regions 401 to 406 formed on the substrate 160 as described above in relation to FIGS. 1 to 4. The deposition blades 570 may be connected to a separate frame (not shown) installed in the vacuum chamber to position the deposition blades 570, or may be disposed in the thin film deposition apparatus 500 that moves up and down to move with the thin film deposition apparatus 500. In this regard, the deposition blades 571 to 573 may respectively disposed in the first direction of the substrate 160 to cover the first non-deposition regions 407 that partition the space between a plurality of deposition regions 401 to 401 arranged in the second direction of the substrate 160.

The deposition blades 570 are not disposed along the second direction of the substrate 160. Since the deposition of the deposition material 112 on the second non-deposition regions 408 that partition the deposition regions arranged in the first direction of the substrate 160 may be prevented by the second nozzle frame 152 including the second nozzle 150 that moves up and down, there is no need to install the deposition blades 570.

Alternatively, the deposition blades 570 may also be disposed in the first direction of the substrate 160 and in the second direction perpendicular to the first direction, respectively. Any other structure in which the deposition blades 570 cover the non-deposition regions of the substrate 160 may also be used without limitation

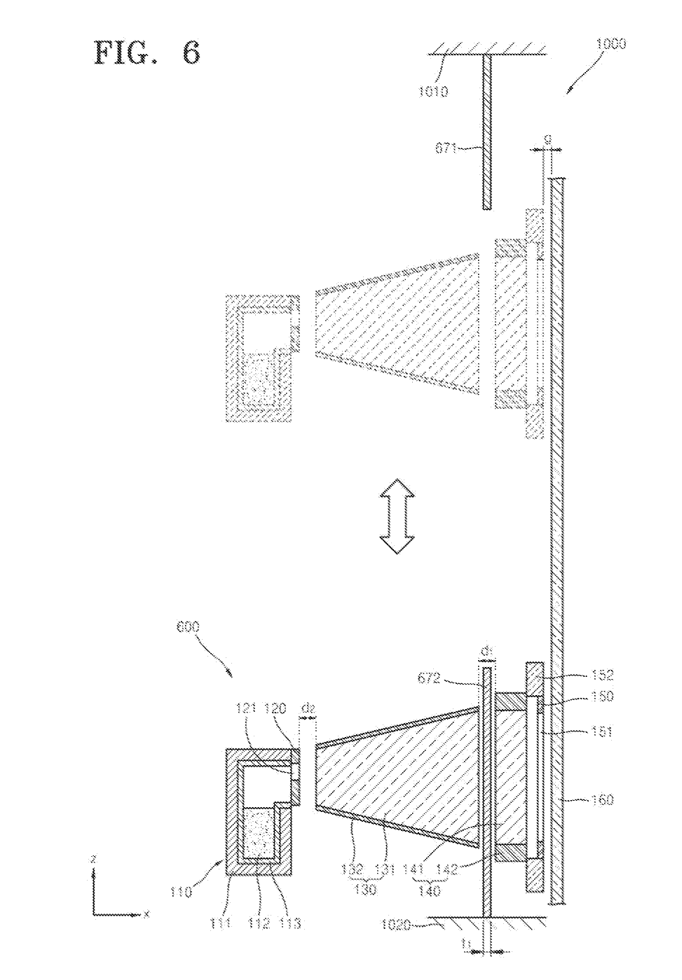

FIG. 6 is a schematic side view of a thin film deposition apparatus 600 according to another embodiment of the present invention. Referring to FIG. 6, the thin film deposition apparatus 600 includes a deposition source 110, a first nozzle 120, a first barrier wall assembly 130, a second barrier wall assembly 140, a second nozzle 150, and a substrate 160. The thin film deposition apparatus 600 is disposed in a vacuum chamber maintained at an appropriate vacuum in order to allow a deposition material 112 vaporized in the deposition source 110 to move straight. In this regard, once the operation of the thin film deposition apparatus 600 is started, the temperature of the thin film deposition apparatus 100 should be constantly maintained without turning off the deposition source 110 until the deposition material 112 is exhausted in order to prevent denaturation of the deposition material 112, e.g., an organic material.

In this case, even during a stand-by mode between one deposition process of one substrate 160 and a subsequent deposition process for another substrate, the deposition material 112 is continuously discharged to a vacuum chamber 1000 through the second nozzle 150 to be deposited on the second nozzle 150. To prevent this deposition during a stand-by mode, a first deposition blade 671 is disposed at an upper portion 1010 of the vacuum chamber 1000 and a second deposition blade 672 is disposed at a lower portion 1020 of the vacuum chamber 1000. The first deposition blade 671 and the second deposition blade 672 are fixed at positions corresponding to the space (d1) between the first barrier wall assembly 130 and the second barrier wall assembly 140. The thicknesses (t1) of the first deposition blade 671 and the second deposition blade 672 are less than the distance (d1) between the first barrier wall assembly 130 and the second barrier wall assembly 140. While shown as connected to the sides 1010, 1020 of the vacuum chamber 1000, it is understood that the first deposition blade 671 and/or the second deposition blade 672 could instead be held by a frame such as that shown in FIG. 4.

If the first deposition blade 671 and the second deposition blade 672 are disposed between the first barrier wall assembly 130 and the second barrier wall assembly 140, the deposition material 112 discharged from the deposition source 110 is prevented from reaching the second nozzle 150, and therefore may not be adhered to undesirable regions such as the second nozzle 150.

When one deposition on one substrate 560 is completed, the thin film deposition apparatus 600 is moved up and down to enter a stand-by mode. Thus, the thin film deposition apparatus 600 is moved upward or downward. However, the deposition material 112 is continuously vaporized by the deposition source 110 during the stand-by mode. Thus, the deposition material 112 is deposited on the second nozzle 150. Since the width of the pattern of the second nozzle 150 is reduced due to the continuous deposition of the deposition material 112, the exchange cycle of the second nozzle 150 is reduced.

The first barrier wall assembly 130 and the second barrier wall assembly 140 are thus positioned to be separated by the first deposition blade 671 or the second deposition blade 672 at the upper portion 1010 or the lower portion 1020 of the vacuum chamber 1000. Therefore, the deposition material 112 is adhered to surfaces of the first deposition blade 671 and the second deposition blade 672. Thus, the deposition of the deposition material 112 on the second nozzle 150 may be minimized.

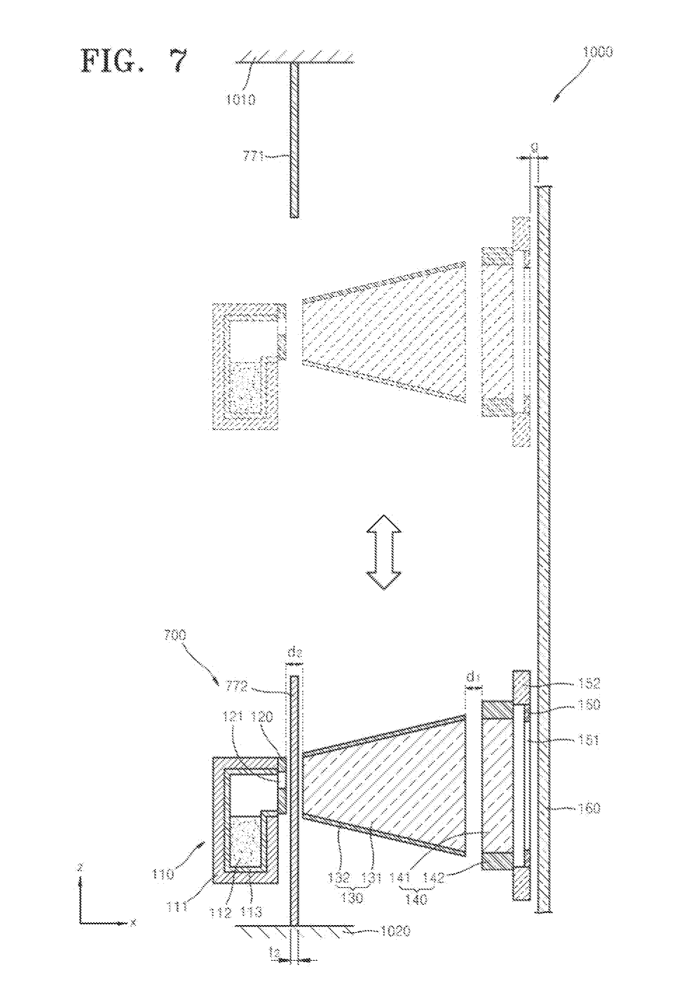

FIG. 7 is a schematic side view of a thin film deposition apparatus 700 according to another embodiment of the present invention. Referring to FIG. 7, a first deposition blade 771 is disposed at an upper portion 1010 of the vacuum chamber 1000 and a second deposition blade 772 is disposed at a lower portion 1020 of the vacuum chamber 1000.

The first deposition blade 771 and the second deposition blade 772 are disposed in the space (d2) between the deposition source 110 and the first barrier wall assembly 130. The thicknesses (t2) of the first deposition blade 771 and the second deposition blade 772 are respectively less than the distance (d2) between the deposition source 110 and the first barrier wall assembly 130. As such, if the first deposition blade 771 and the second deposition blade 772 are disposed between the deposition source 110 and the first barrier wall assembly 130, the deposition material 112 discharged from the deposition source 110 may not be adhered to undesirable regions of the vacuum chamber 1000 such as the second nozzle 150.

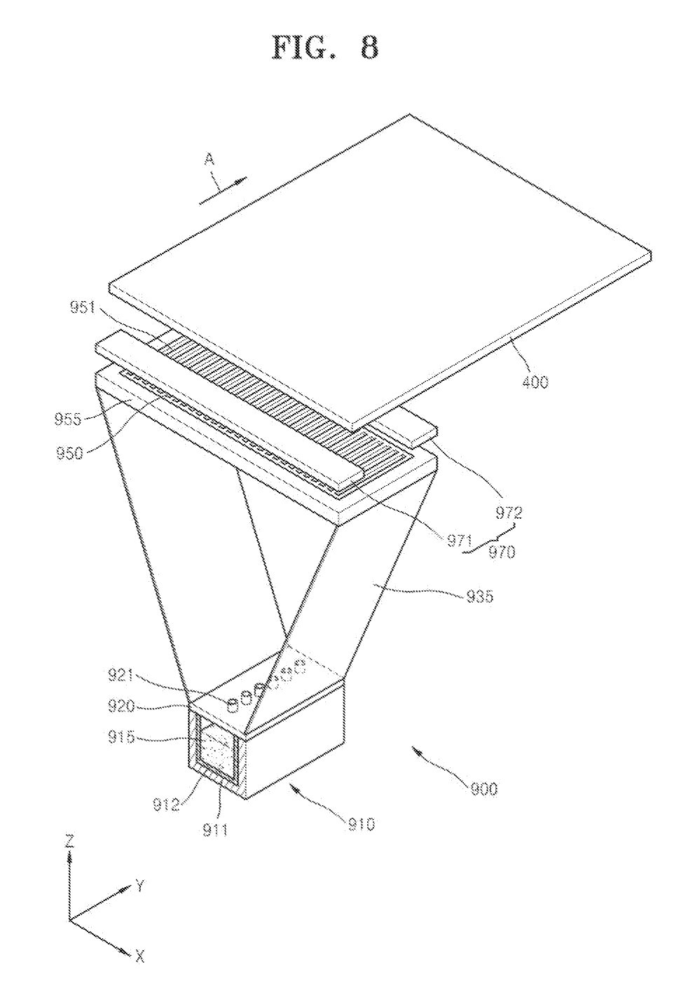

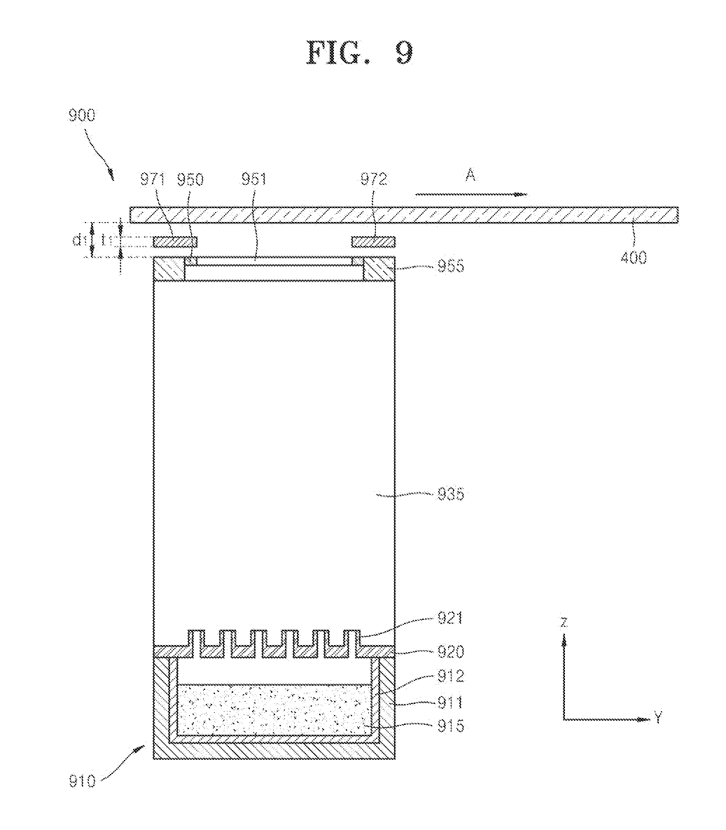

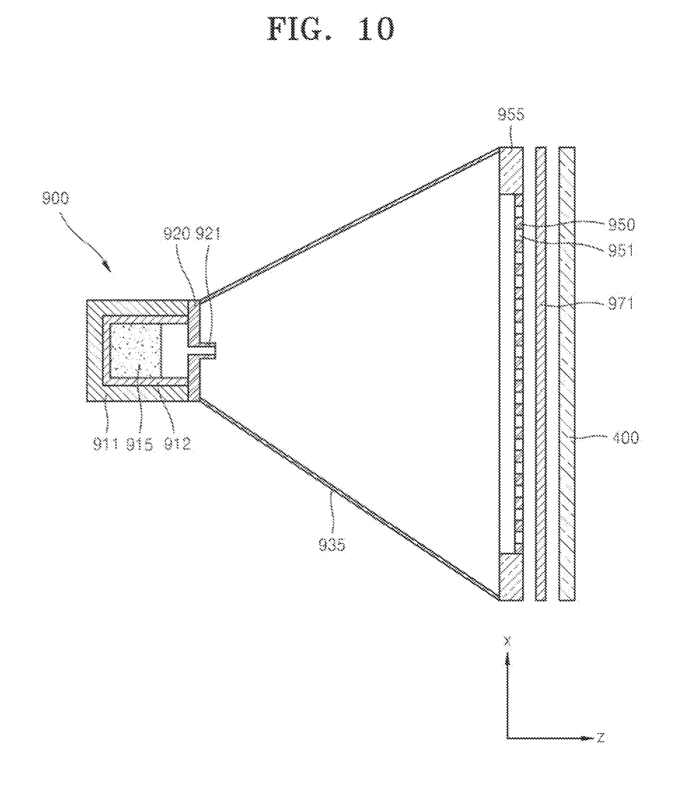

Hereinafter, a thin film deposition apparatus 900 according to another embodiment of the present invention will be described with reference to FIGS. 8 to 10. The thin film deposition apparatus 900 according to the current embodiment does not include a barrier wall assembly. FIG. 8 is a schematic perspective view of a thin film deposition apparatus 900 according to another embodiment of the present invention, FIG. 9 is a schematic side view of the thin film deposition apparatus 900 of FIG. 8, and FIG. 10 is a schematic plan view of the thin film deposition apparatus 900 of FIG. 8. Referring to FIGS. 8, 9 and 10, the thin film deposition apparatus 900 includes a deposition source 910, a first nozzle 920, and a second nozzle 950.

Although a chamber is not illustrated in FIGS. 8, 9 and 10 for convenience of explanation, all the components of the thin film deposition apparatus 900 may be disposed within a chamber that is maintained at an appropriate degree of vacuum. The chamber is maintained at an appropriate vacuum in order to allow a deposition material to move in a substantially straight line through the thin film deposition apparatus 900.

In order to deposit a deposition material 915, the deposition material 915 is discharged from the deposition source 910 and passes through the first nozzle 920 and the second nozzle 950. The discharged deposition material 915 is deposited on a substrate 400 in a desired pattern. The chamber should be maintained in a high-vacuum state as in a deposition method using a fine metal mask (FMM). In addition, the temperature of the second nozzle 950 has to be sufficiently lower than the temperature of the deposition source 910. In this regard, the temperature of the second nozzle 950 may be about 100° C. or less. The temperature of the second nozzle 950 should be sufficiently low so as to reduce thermal expansion of the second nozzle 950.

The substrate 400 constitutes a deposition target on which the deposition material 915 is to be deposited. The substrate 400 is disposed in the chamber. The substrate 400 may be a substrate for flat panel displays. A large substrate, such as a mother glass, for manufacturing a plurality of flat panel displays, may be used as the substrate 400. Other substrates may also be employed.

Here, deposition may be performed while the substrate 400 is moved relative to the thin film deposition apparatus 900. In particular, in the conventional FMM deposition method, the size of the FMM has to be equal to the size of a substrate. Thus, the size of the FMM has to be increased as the substrate becomes larger. However, it is neither straightforward to manufacture a large FMM nor to extend an FMM to be accurately aligned with a pattern.

In order to overcome this problem, in the thin film deposition apparatus 900, deposition may be performed while the thin film deposition apparatus 900 and/or the substrate 400 is moved relative to each other. In other words, deposition may be continuously performed while the substrate 400, which is disposed such as to face the thin film deposition apparatus 900, is moved in a Y-axis direction. Specifically, deposition is performed in a scanning manner while the substrate 400 is moved in a direction of an arrow A in FIG. 8. Although the substrate 400 is illustrated as being moved in the Y-axis direction in FIG. 8 when deposition is performed, the present invention is not limited thereto. Deposition may be performed while the thin film deposition apparatus 900 is moved in the Y-axis direction, whereas the substrate 400 is fixed, or where the apparatus 900 and substrate 400 both move.

In the thin film deposition apparatus 900, the second nozzle 950 may be significantly smaller than a FMM used in a conventional deposition method. Specifically, in the thin film deposition apparatus 900, deposition is continuously performed, i.e., in a scanning manner while the substrate 400 is moved in the Y-axis direction. Thus, lengths of the second nozzle 950 in the Y-axis direction may be significantly less than the lengths of the substrate 400 in the Y-axis direction. As described above, since the second nozzle 950 may be formed to be significantly smaller than a FMM used in a conventional deposition method, it is relatively easy to manufacture the second nozzle 950. The use of the second nozzle 950, which is smaller than a FMM used in a conventional deposition method, is more convenient in all processes, including etching and subsequent other processes, such as precise extension, welding, moving, and cleaning processes, compared to the conventional deposition method using the larger FMM. This is more advantageous for a relatively large display device.

In order to perform deposition while the thin film deposition apparatus 900 or the substrate 400 is moved relative to each other as described above, the thin film deposition apparatus 900 and the substrate 400 may be separated from each other by a predetermined distance.

The deposition source 910 contains and heats the deposition material 915. The deposition source 910 is disposed on a side of the chamber opposite to a side on which the substrate 400 is disposed. As the deposition material 915 contained in the deposition source 910 is vaporized, the deposition material 915 is deposited on the substrate 400.

The deposition source 910 includes a crucible 911 and a heater 912. The crucible 911 holds the deposition material 915. The heater 912 heats the crucible 911 to vaporize the deposition material 915 contained in the crucible 911 towards a side of the crucible 911, and in particular, towards the first nozzle 920.

The first nozzle 920 is disposed at a side of the deposition source 910 facing the substrate 400. The first nozzle 920 includes a plurality of first slits 921 arranged at equal intervals in a Y-axis direction (that is the scanning direction of the substrate 400). The deposition material 915 that is vaporized in the deposition source 910 passes through the first nozzle 920 towards the substrate 400. As described above, when the first slits 921 are formed on the first nozzle 920 in the Y-axis direction, a size of the pattern formed by the deposition material 915 that is discharged through each of second slits 951 of the second nozzle 950 is only affected by the size of one first slit 921, that is, it may be considered that one first slit 921 exists in the X-axis direction, and thus there is no shadow zone on the substrate 400. In addition, since the first slits 921 are formed in the scanning direction of the substrate 400, even if there is a difference between fluxes of the first slits 921, the difference may be compensated and deposition uniformity may be maintained constantly.

The second nozzle 950 and a second nozzle frame 955 are disposed between the first nozzle 920 and the substrate 400. The second nozzle frame 955 may be formed in a lattice shape, similar to a window frame, but the invention is not limited thereto. The second nozzle 950 is bound inside the second nozzle frame 955. The second nozzle 950 includes a plurality of second slits 951 arranged at equal intervals in the X-axis direction and which are elongated in the Y-axis direction. The deposition material 915 that is vaporized in the deposition source 910 passes through the first nozzle 920 and the second nozzle 950 towards the substrate 400. The second nozzle 950 may be manufactured by etching, which is the same method as used in a conventional method of manufacturing an FMM, and in particular, a striped FMM. Here, the total number of second slits 951 may be greater than the total number of first slits 921.

The deposition source 910 (and the first nozzle 920 coupled to the deposition source 910) and second nozzle 950 are separated from each other by a predetermined distance. Alternatively, the deposition source 110 (and the first nozzle 920 coupled to the deposition source 910) and the second nozzle 950 may be connected by a connection member 935. That is, the deposition source 910, the first nozzle 920, and the second nozzle 950 may be formed integrally with each other by being connected to each other via the connection member 935. The connection member 935 guides the deposition material 915, which is discharged through the first slits 921, to move straight and not to flow in the X-axis direction. In FIGS. 8 through 10, the connection members 935 are formed on left and right sides of the deposition source 910, first nozzle 920, and second nozzle 950 to guide the deposition material 915 not to flow in the X-axis direction, however, the present invention is not limited thereto. That is, the connection member 935 may be formed as a sealed type of a box shape to guide flow of the deposition material 915 in the X-axis and Y-axis directions.

As described above, the thin film deposition apparatus 900 performs deposition while being moved relative to the substrate 400. In order to move the thin film deposition apparatus 900 relative to the substrate 400, the second nozzle 950 is separated from the substrate 400 by a predetermined distance.

In particular, in a conventional deposition method using a FMM, deposition is performed with the FMM in close contact with a substrate in order to prevent formation of a shadow zone on the substrate. However, when the FMM is used in close contact with the substrate, the contact may cause defects. In addition, in the conventional deposition method, the size of the mask has to be the same as the size of the substrate since the mask cannot be moved relative to the substrate. Thus, the size of the mask has to be increased as display devices become larger. However, it is not easy to manufacture such a large mask.

In order to overcome this problem, in the thin film deposition apparatus 900, the second nozzle 950 is disposed to be separated from the substrate 400 by a predetermined distance. As described above, a mask is formed to be smaller than the substrate 400, and deposition is performed while the mask is moved relative to the substrate 400. Thus, the mask can be easily manufactured. In addition, defects caused due to the contact between a substrate and a FMM, which occurs in the conventional deposition method, may be prevented. In addition, since it is unnecessary to use the mask in close contact with the substrate 400 during a deposition process, the manufacturing speed may be improved.

In the thin film deposition assembly 900, a plurality of deposition blades 970 may be disposed at any space formed between two adjacent units selected from the group consisting of the deposition source 910, the first nozzle 920, the second nozzle 950, and the substrate 400. The deposition blade 970 is shown disposed in the space (d1) between the second nozzle 950 and the substrate 400. For this, the thickness (t1) of the deposition blade 970 is less than the distance (d1) between the second nozzle 950 and the substrate 400 to be disposed between the second nozzle 950 and the substrate 400. The deposition blade 970 has been described in detail with reference to the previous embodiment, and thus detailed descriptions thereof will not be provided here.

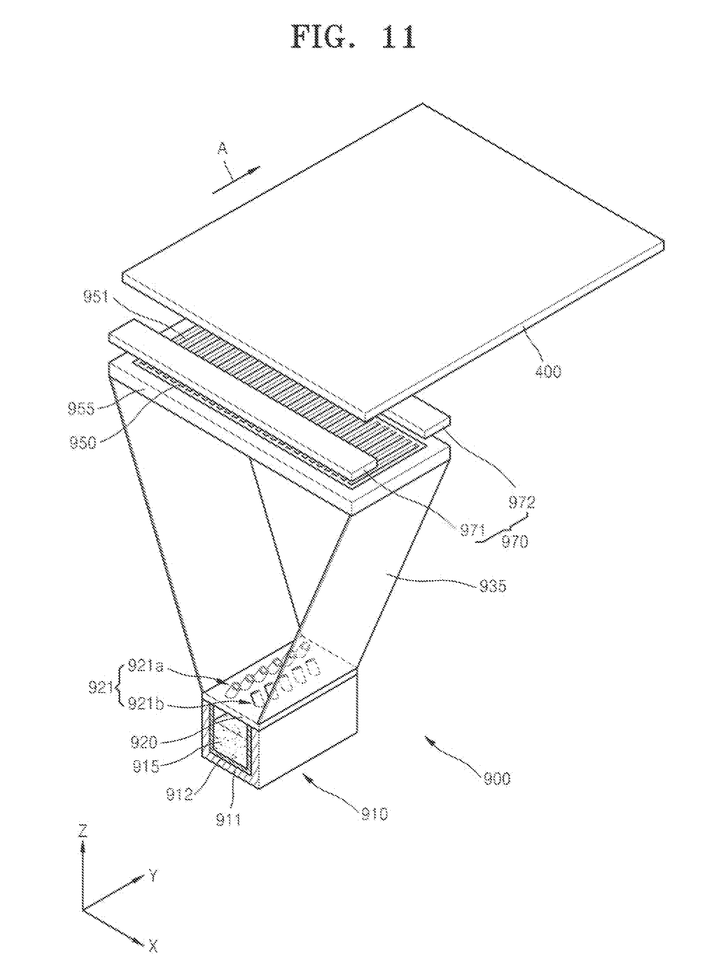

Hereinafter, a thin film deposition apparatus 900 according to another embodiment of the present invention will be described with reference to FIG. 11. In the current embodiment of the present invention, the plurality of deposition first slits 921 formed on the first nozzle 920 are tilted at a predetermined angle. Referring to FIG. 11, the thin film deposition apparatus 900 includes a deposition source 910, a first nozzle 920, and a second nozzle 950. In this regard, the deposition source 910 includes a crucible 911 that is filled with the deposition material 915, and a heater 912 that heats the crucible 911 to vaporize the deposition material 915, which is contained in the crucible 911, towards the first nozzle 920.

The first nozzle 920 is disposed at a side of the deposition source 910. The first nozzle 920 includes a plurality of first slits 921 arranged in the Y-axis direction. The second nozzle 950 and a second nozzle frame 955 are further disposed between the deposition source 910 and the substrate 400, and the second nozzle 950 includes a plurality of second slits 951 arranged in the X-axis direction. In addition, the first deposition source 910, the first nozzle 920, and the second nozzle 950 are connected to each other by a connection member 935.

In the current embodiment, the first slits 921 formed on the first nozzle 920 are tilted at a predetermined angle. In particular, the first slits 921 includes first slits 921a and 921b which are arranged in two rows, which are alternately arranged with each other. Here, the first slits 921a and 121b are tilted at a predetermined angle in the XZ plane.

That is, in the current embodiment, the first slits 921a and 921b are arranged to be tilted at a predetermined angle. The first slits 921a in a first row are tilted toward the first slits 921b in a second row. The first slits 921b in the second row are tilted toward the first slits 921a in the first row. In other words, the first slits 921a arranged in the row at the left side of first nozzle 920 are arranged to face the right side of the second nozzle 950, and the first slits 921b arranged in the row at the right side of first nozzle 920 are arranged to face the left side of the second nozzle 950.

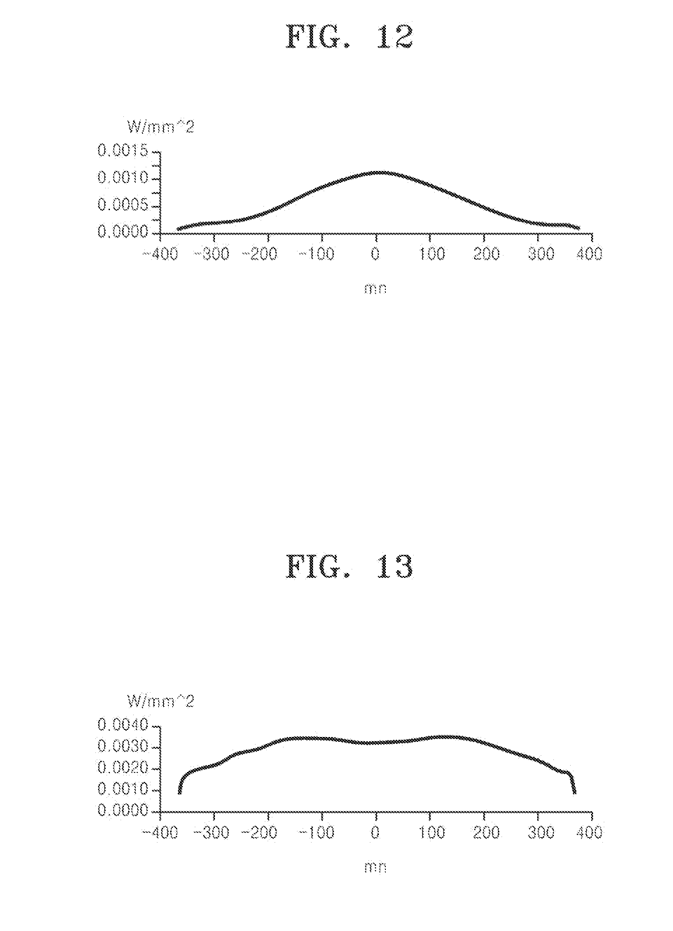

FIG. 12 is a graph schematically illustrating a distribution pattern of a deposition layer formed on the substrate 400 when first slits 921 are not tilted as shown in FIG. 8. FIG. 13 is a graph schematically illustrating a distribution pattern of a deposition layer formed on the substrate 400 when first slits 921 are tilted. Comparing the graphs of FIGS. 12 and 13 with each other, a thickness of the deposition layer formed on both end portions of the substrate 400 when the first slits 921 are tilted is relatively greater than that of the deposition layer formed on the substrate 400 when the first slits 921 are not tilted. Thus, the uniformity of the deposition layer is improved by tilting the slits 921.

Therefore, the deposition amount of the deposition material may be adjusted so that a difference between the thicknesses of the deposition layer at the center portion and end portions of the substrate may be reduced and the entire thickness of the deposition layer may be constant. Moreover, the efficiency of utilizing the deposition material may be improved.

In the thin film deposition assembly 900, a plurality of deposition blades 970 may be disposed at any space formed between two adjacent units selected from the group consisting of the deposition source 910, the first nozzle 920, the second nozzle 950, and the substrate 400. The deposition blade 970 is disposed in the space (d1) between the second nozzle 950 and the substrate 400. For this, the thickness (t1) of the deposition blade 970 is less than the distance (d1) between the second nozzle 950 and the substrate 400 to be disposed between the second nozzle 950 and the substrate 400. The deposition blade 970 has been described in detail with reference to the previous embodiment, and thus detailed descriptions thereof will not be provided here.

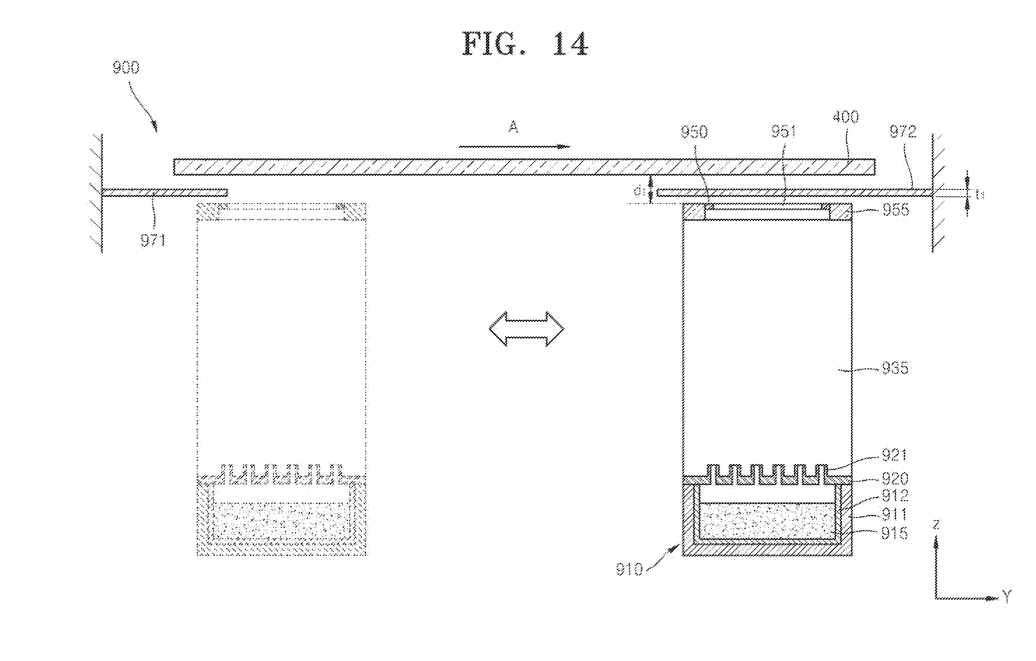

FIG. 14 is a schematic side view of a thin film deposition apparatus 900 according to another embodiment of the present invention. Referring to FIG. 14, the thin film deposition apparatus 900 includes a deposition source 910, a first nozzle 920, a second nozzle 950, and a substrate 400. The thin film deposition apparatus 900 is disposed in a vacuum chamber maintained at an appropriate vacuum in order to allow a deposition material 915 vaporized in the deposition source 910 to move straight.

In this regard, once the operation of the thin film deposition apparatus 900 is started, the temperature of the thin film deposition apparatus 900 should be constantly maintained without turning off the deposition source 910 until the deposition material 915 is exhausted in order to prevent denaturation of the deposition material 915, e.g., an organic material. In this case, even during a stand-by mode between one deposition process of one substrate 400 and a subsequent deposition process for another substrate, the deposition material 915 is continuously discharged to a vacuum chamber through the second nozzle 950 to be deposited in the vacuum chamber.

To prevent the continuous deposition, a first deposition blade 971 is disposed at an upper portion of the vacuum chamber and a second deposition blade 972 is disposed at a lower portion of the vacuum chamber. The first deposition blade 971 and the second deposition blade 972 are fixed at positions corresponding to the space (d1) between the second nozzle 950 and the substrate 400. The thicknesses (t1) of the first deposition blade 971 and the second deposition blade 972 are less than the distance (d1) between the second nozzle 950 and the substrate 400.

As described above, if the first deposition blade 971 and the second deposition blade 972 are disposed between the second nozzle 950 and the substrate 400, the deposition material 915 discharged from the deposition source 910 may not be adhered to undesirable regions of the vacuum chamber.

When one deposition on one substrate 400 is completed, the thin film deposition apparatus 900 enters a stand-by mode. Accordingly, the thin film deposition apparatus 900 is moved upward or downward of the vacuum chamber.

However, the deposition material 915 is continuously vaporized by the deposition source 910 during the stand-by mode. Thus, the deposition material 915 is deposited in the vacuum chamber if there is no blade 971,972. Therefore, utilization of the deposition material 915 is significantly reduced.

As shown, the second nozzle 950 and the substrate 400 are positioned to be separated by the first deposition blade 971 or the second deposition blade 972 at the upper or lower portion of the vacuum chamber. Thus, the deposition material 915 is adhered to surfaces of the first deposition blade 971 and the second deposition blade 972. Therefore, the deposition of the deposition material 915 in the vacuum chamber may be minimized.

The thin film deposition apparatus including the deposition blade according to embodiments of the present invention as described above may have one or more of the following effects. Since the deposition blade is disposed in any space formed between each two adjacent units selected from the group consisting of the deposition source, the first nozzle, the barrier wall assembly, the second nozzle, and the substrate, the deposition of the deposition material on the non-deposition regions of the substrate may be minimized during a deposition process. Since the deposition blade is disposed in any space formed between each two adjacent units selected from the group consisting of the deposition source, the first nozzle, the barrier wall assembly, the second nozzle, and the substrate, at an upper or lower portion of the vacuum chamber during a stand-by mode, the deposition of the deposition material that is continuously discharged from the deposition source during the stand-by mode on undesirable regions of the vacuum chamber may be minimized during the stand-by mode.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A thin film deposition apparatus for use with a substrate having a plurality of deposition regions and a plurality of non-deposition regions formed between the deposition regions to partition the deposition regions, the thin film deposition apparatus comprising:
a deposition source, a first nozzle assembly disposed in front of the deposition source, at least one barrier wall assembly disposed in front of the first nozzle assembly, and a second nozzle assembly disposed between the barrier wall assembly and the substrate; and
at least one deposition blade corresponding to one of the non-deposition regions of the substrate and disposed such that, during a relative motion between the thin film deposition apparatus and the substrate, the at least one deposition blade passes through a gap between one of adjacent pairs of the deposition source, the first nozzle assembly, the barrier wall assembly, the second nozzle assembly, and the substrate.

2. The thin film deposition apparatus of claim 1, wherein:
the deposition source is disposed opposite to the substrate and comprises a deposition material that is vaporized,
the first nozzle assembly comprises a first nozzle that comprises a plurality of first slits arranged in a first direction of the substrate and a first nozzle frame that supports the first nozzle,
the barrier wall assembly comprises a plurality of barrier walls arranged between the first nozzle assembly and the second nozzle assembly to partition a space between the first nozzle assembly and the second nozzle assembly; and
the second nozzle assembly comprises a second nozzle that comprises a plurality of second slits arranged in the first direction of the substrate and a second nozzle frame that supports the second nozzle.

3. The thin film deposition apparatus of claim 1, wherein:
the non-deposition regions comprise:
first non-deposition regions formed along the first direction of the substrate and separating corresponding pairs of the deposition regions which are adjacent in a second direction of the substrate perpendicular to the first direction, and
second non-deposition regions formed along the second direction of the substrate and separating corresponding pairs of the deposition regions which adjacent in the first direction, and
the at least one deposition blade comprises a plurality of the deposition blades which respectively cover the first non-deposition regions while the deposition material is deposited on the deposition regions.

4. The thin film deposition apparatus of claim 3, wherein a width of each of the deposition blades in the second direction is substantially the same as a width of the first non-deposition regions in the second direction.

5. The thin film deposition apparatus of claim 3, wherein the second nozzle assembly further covers the second non-deposition regions when the thin film deposition apparatus is moved up and down in a third direction perpendicular to the first and second directions.

6. The thin film deposition apparatus of claim 3, wherein additional deposition blades further cover the second non-deposition regions while the deposition material is deposited on the deposition regions.

7. The thin film deposition apparatus of claim 1, wherein:
the barrier wall assembly comprises a first barrier wall assembly disposed between the first nozzle assembly and the second nozzle assembly and a second barrier wall assembly disposed between the first barrier wall assembly and the second nozzle assembly, and
the gap through which the at least one deposition blade passes is between the first barrier wall assembly and the second barrier wall assembly.

8. The thin film deposition apparatus of claim 7, wherein a thickness of the at least one deposition blade is less than a height of the gap between the first barrier wall assembly and the second barrier wall assembly.

9. The thin film deposition apparatus of claim 7, wherein:
the first barrier wall assembly comprises a plurality of first barrier walls spaced apart from each other in a first direction of the substrate,
each of the first barrier walls extends along a second direction perpendicular to the first direction,
the second barrier wall assembly comprises a plurality of second barrier walls spaced apart from each other in the first direction of the substrate,
each of the second barrier walls extends along the second direction perpendicular to the first direction, and
the second barrier walls are respectively disposed to be parallel to and coplanar with the first barrier walls with respect to the substrate to partition a space between the first nozzle assembly and the second nozzle assembly.

10. The thin film deposition apparatus of claim 9, wherein:
the first barrier wall assembly further comprises a first barrier wall frame which surrounds the plurality of the first barrier walls, and
the second barrier wall assembly further comprises a second barrier wall frame which surrounds the plurality of the second barrier walls.

11. The thin film deposition apparatus of claim 1, wherein the gap through which the at least one deposition blade passes is between the deposition source and the barrier wall assembly.

12. The thin film deposition apparatus of claim 1, further comprising:
a frame which holds the at least one deposition blade at the gap, and
a vacuum chamber which houses the thin film deposition apparatus, the frame, and the substrate during deposition.

13. The thin film deposition apparatus of claim 2, wherein:
the first slits are arranged at equal intervals in the first direction,
the second slits are arranged at equal intervals in the first direction, and
a number of the second slits disposed between two adjacent barrier walls is greater than a number of the first slits disposed between the two adjacent barrier walls.

14. A thin film deposition apparatus for depositing a deposition material on a substrate, the thin film deposition assembly comprising:
a thin film deposition apparatus comprising a deposition source, a first nozzle assembly disposed in front of the deposition source, at least one barrier wall assembly disposed in front of the first nozzle assembly, and a second nozzle assembly disposed between the barrier wall assembly and the substrate;
a vacuum chamber housing the deposition source, the first nozzle assembly, the barrier wall assembly, the second nozzle assembly, and the substrate; and
a deposition blade connected to the vacuum chamber so as to extend in a gap formed between adjacent pairs of the deposition source, the first nozzle assembly, the barrier wall assembly, the second nozzle assembly, and the substrate when the thin film deposition apparatus is moved up and down at an upper or lower portion of the vacuum chamber while in a stand-by mode.

15. The thin film deposition apparatus of claim 14, wherein:
the deposition source is disposed opposite to the substrate and comprises a deposition material that is vaporized,
the first nozzle assembly comprises a first nozzle that comprises a plurality of first slits arranged in a first direction of the substrate,
the barrier wall assembly comprises a plurality of barrier walls arranged between the first nozzle assembly and the second nozzle assembly to partition a space between the first nozzle assembly and the second nozzle assembly, and
the second nozzle assembly comprises a second nozzle that comprises a plurality of second slits arranged in the first direction of the substrate.

16. The thin film deposition apparatus of claim 14, wherein:
the deposition blade comprises a first deposition blade that is fixed to the upper portion of the vacuum chamber,
the thin film deposition assembly further comprises a second deposition blade that is fixed to the lower portion of the vacuum chamber, and
the thin film deposition apparatus is disposed between the first and second deposition blades.

17. The thin film deposition apparatus of claim 14, wherein the barrier wall assembly comprises a first barrier wall assembly disposed between the first nozzle assembly and the second nozzle assembly and a second barrier wall assembly disposed between the first barrier wall assembly and the second nozzle assembly, and
the gap in which the deposition blade is disposed during the stand-by mode is between the first barrier wall assembly and the second barrier wall assembly.

18. The thin film deposition apparatus of claim 17, wherein a thickness of the deposition blade is less than a height of the gap between the first barrier wall assembly and the second barrier wall assembly.

19. The thin film deposition apparatus of claim 17, wherein:
the first barrier wall assembly comprises a plurality of first barrier walls spaced apart from each other in a first direction of the substrate,
each of the first barrier walls extends along a second direction of the substrate perpendicular to the first direction,
the second barrier wall assembly comprises a plurality of second barrier walls arranged in the first direction of the substrate,
each of the second barrier walls extends along the second direction perpendicular to the first direction, and
the second barrier walls are respectively disposed to be parallel to and coplanar with the first barrier walls with respect to the substrate to partition a space between the first nozzle assembly and the second nozzle assembly.

20. The thin film deposition apparatus of claim 19, further comprising another deposition blade that is further disposed in the gap between the first barrier walls and the second barrier walls to cover at least one non-deposition region of the substrate during a deposition process so as to prevent a deposition material from the deposition source from being deposited on the at least one non-deposition region.

21. The thin film deposition apparatus of claim 19, wherein:
the first barrier wall assembly further comprises a first barrier wall frame which surrounds the plurality of the first barrier walls, and
the second barrier walls further comprises a second barrier wall frame which surrounds the plurality of the second barrier walls.

22. The thin film deposition apparatus of claim 14, wherein the gap in which the deposition blade is disposed during the stand-by mode is between the deposition source and the barrier wall assembly.

23. The thin film deposition apparatus of claim 15, wherein:
the first slits are arranged at equal intervals in the first direction of the substrate,
the second slits are formed in the second nozzle assembly at equal intervals in the first direction of the substrate, and
a number of the second slits disposed between two adjacent barrier walls is greater than a number of the first slits disposed between the two adjacent barrier walls.

24. The thin film deposition apparatus of claim 14, wherein:
the gap is between the deposition source and the first barrier walls, and the thin film deposition assembly further comprises another deposition blade disposed in the gap between the deposition source and the first barrier walls to cover at least one non-deposition region of the substrate during a deposition process so as to prevent a deposition material from the deposition source from being deposited on the at least one non-deposition region.

25. A thin film deposition apparatus for forming a thin film on a substrate that comprises a plurality of deposition regions and a plurality of non-deposition regions formed between the deposition regions to partition the deposition regions, the thin film deposition apparatus comprising:
a deposition source that discharges a deposition material;
a first nozzle disposed at a side of the deposition source and comprising a plurality of first slits arranged in a first direction;
a second nozzle disposed opposite to the first nozzle and comprising a plurality of second slits arranged in a second direction perpendicular to the first direction; and
at least one deposition blade disposed to cover at least one of the non-deposition regions of the substrate,
wherein, while a deposition is performed, the substrate moves relative to the thin film deposition apparatus in the first direction and the at least one deposition blade passes between a gap between the deposition source and the first nozzle, between the first nozzle and the second nozzle, or between the second nozzle and the substrate.

26. The thin film deposition apparatus of claim 25, wherein:
the non-deposition regions comprise:
first non-deposition regions formed along a second direction and separating corresponding pairs of deposition regions which are adjacent in the first direction, and
second non-deposition regions formed along the first direction and separating corresponding pairs of the plurality of deposition regions which are adjacent in the second direction, and
the at least one deposition blade comprises deposition blades which respectively cover the first non-deposition regions while the deposition material is deposited.

27. The thin film deposition apparatus of clam 26, wherein a width of each of the deposition blades in the first direction is substantially the same as a width of the first non-deposition regions in the first direction.

28. The thin film deposition apparatus of clam 26, further comprising additional deposition blades which respectively cover the second non-deposition regions while the deposition material is deposited.

29. The thin film deposition apparatus of clam 25, wherein the gap through which the deposition blade passes is between the substrate and the second nozzle.

30. The thin film deposition apparatus of clam 29, wherein a thickness of the deposition blade is less than a height of the gap between the substrate and the second nozzle.

31. The thin film deposition apparatus of clam 25, further comprising a vaccum chamber which houses the deposition source, the first nozzle, the second nozzle, and the at least one deposition blade, wherein the deposition blade is connected to the vacuum chamber.

32. The thin film deposition apparatus of clam 31, wherein the deposition blade is connected to the vacuum chamber so to be in the gap when the thin film deposition apparatus is moved to a side of the vacuum chamber during a stand-by mode.

33. The thin film deposition apparatus of clam 25, further comprising a connection member which connects the deposition source, the first nozzle, and the second nozzle.

34. The thin film deposition apparatus of clam 33, wherein the connection member guides a movement of the discharged deposition material.

35. The thin film deposition apparatus of clam 33, wherein the connection member seals a space between the deposition source, the first nozzle, and the second nozzle.

36. The thin film deposition apparatus of clam 25, wherein the second nozzle is separated from the substrate by a predetermined distance.

37. The thin film deposition apparatus of clam 25, wherein the deposition material discharged through the second nozzle is continuously deposited on the substrate while the substrate is moved relative to the second nozzle in the first direction.

38. The thin film deposition apparatus of clam 25, wherein the second nozzle is smaller than the substrate.

39. The thin film deposition apparatus of clam 25, wherein each of the plurality of first slits is tilted at a predetermined angle.

40. The thin film deposition apparatus of clam 39, wherein the first slits are arranged in two rows formed in the first direction, and the first slits in a first one of the rows are tilted at the predetermined angle towards the first slits in a second of the rows.

41. The thin film deposition apparatus of clam 39, wherein:
the first slits comprise first slits arranged in first and second rows formed in the first direction,
the first slits arranged in the first row located at a first side are arranged to face a second side of the second nozzle, and
the first slits arranged in the second row located at the second side are arranged to face the first side of the second nozzle.

42. A thin film deposition assembly for use with a substrate having a non-deposition region between adjacent pairs of deposition regions, the thin film deposition assembly comprising:
a thin film deposition apparatus comprising a deposition source, a first nozzle assembly, and a second nozzle assembly disposed between the first nozzle assembly and the substrate such that a deposition material from the deposition source passes through the first and second nozzle assemblies and is deposited on the deposition regions; and
a deposition blade disposed such that, due to a relative motion between the thin film deposition apparatus and the substrate, the deposition blade passes relative to the deposition source to block the deposition material such that the deposition material is deposited on the deposition blade.

43. The thin film deposition assembly of claim 42, wherein the deposition blade corresponds to the non-deposition region of the substrate and is disposed such that, during the relative motion between the thin film deposition apparatus and the substrate, the deposition blade passes between the deposition source and the substrate to prevent the deposition material from being deposited on the non-deposition region while allowing the deposition material to be deposited on the deposition regions.

44. The thin film deposition assembly of claim 42, wherein the deposition blade corresponds to the second nozzle assembly and is disposed such that, while between the thin film deposition apparatus and the substrate, the deposition blade passes between the deposition source and the second nozzle assembly to prevent the deposition material from being deposited on the second nozzle assembly.

45. The thin film deposition assembly of claim 44, wherein the deposition blade is disposed between the deposition source and the second nozzle assembly during a stand-by mode in which the substrate is exchanged for another substrate, and is not disposed between the deposition source and the second nozzle assembly during a deposition process in which the deposition material is deposited on the substrate.

46. The thin film deposition assembly of claim 42, further comprising a frame which holds the deposition blade relative to a gap disposed between the deposition source and the substrate and through which the deposition blade passes to block the deposition material.

47. The thin film deposition assembly of claim 46, wherein the deposition blade corresponds to the non-deposition region of the substrate and is held by the frame such that, during the relative motion between the thin film deposition apparatus and the substrate, the deposition blade passes through the gap to prevent the deposition material from being deposited on the non-deposition region.

48. The thin film deposition assembly of claim 42, further comprising a vacuum chamber which houses the thin film deposition apparatus, wherein the deposition blade extends from a wall of the vacuum chamber.

49. The thin film deposition assembly of claim 48, wherein the deposition blade corresponds to the second nozzle assembly and is disposed such that, while between the thin film deposition apparatus and the substrate, the deposition blade passes between the deposition source and the second nozzle assembly to prevent the deposition material from being deposited on the second nozzle assembly.

50. The thin film deposition assembly of claim 49, wherein the deposition blade is disposed between the deposition source and the second nozzle assembly during a stand-by mode in which the substrate is exchanged for another substrate, and is not disposed between the deposition source and the second nozzle assembly during a deposition process in which the deposition material is deposited on the substrate.

51. The thin film deposition assembly of claim 50, further comprising another deposition blade which corresponds to the non-deposition region of the substrate and is disposed such that, during the relative motion between the thin film deposition apparatus and the substrate, the deposition blade passes between the deposition source and the substrate to prevent the deposition material from being deposited on the non-deposition region while allowing the deposition material to be deposited on the deposition regions.

52. A method of manufactuing a thin film comprising:
passing a deposition material from a thin film deposition apparatus comprising a deposition source housing the deposition material, a first nozzle assembly, and a second nozzle assembly disposed between the first nozzle assembly and a substrate such that deposition material from the deposition source passes through the first and second nozzle assemblies;
passing a deposition blade disposed such that, due to a relative motion between the thin film deposition apparatus and the substrate, the deposition blade passes between the deposition source and the substrate to block the deposition material; and
depositing the passed deposition material such that the deposition material is deposited on the deposition blade when the deposition blade passes between the deposition source and the substrate and on the substrate when the deposition blade is not between the deposition source and the substrate.

53. The method of claim 52, wherein:
the deposition blade corresponds to a non-deposition region of the substrate, and
the passing the deposition blade comprises passing the deposition blade between the deposition source and the substrate to prevent the deposition material from being deposited on the non-deposition region of the substrate while allowing deposition on deposition regions of the substrate which are separated by the non-deposition region.

54. The method of claim 52, further comprising entering a stand-by mode during which the substrate is replaced with another substrate, wherein the passing the deposition blade comprises passing the deposition blade between the deposition source and the second nozzle assembly to prevent the deposition material from being deposited on the second nozzle assembly.
